(19) United States
(12) Patent Application Publication
(10) Pub. No.: US 2016/0187425 A1
(43) Pub. Date: Jun. 30, 2016

(54) METHOD FOR IDENTIFYING POLE SLIP

(71) Applicant: GE Jenbacher GmbH & Co OG, Jenbach (AT)

(72) Inventor: Albert FAHRINGER, Koessen (AT)

(21) Appl. No.: 14/817,544

(22) Filed: Aug. 4, 2015

Related U.S. Application Data
(63) Continuation of application No. PCT/AT2014/000023, filed on Feb. 5, 2014.

(30) Foreign Application Priority Data
Feb. 28, 2013 (AT) 156/2013

(51) Int. Cl. G01R 31/34; G01P 3/00; H02P 9/00

(52) U.S. Cl. CPC G01R 31/343; H02P 9/006; G01P 3/00

(57) ABSTRACT

Method for identifying pole slip of an electrical generator (2), in particular synchronous generator, which is electrically connected to a power supply system (1), wherein a rotor (3) of the generator (2) is mechanically connected to a motor shaft (4) of an internal combustion engine (5), in particular of a gas engine, wherein the internal combustion engine (5) is operated at a substantially constant mechanical rotation frequency (n) in a stationary operating mode, wherein the mechanical rotation frequency (n) of the motor shaft (4) and an electrical rotation frequency (f) of the power supply system (1) are detected or ascertained, wherein a signal (11) is output in the event of a deviation (6) in the mechanical rotation frequency (n) from the electrical rotation frequency (f) of greater than a prespecifiable threshold value (7), wherein the signal (11) is considered to be a detected pole slip.

The invention concerns a method of identifying pole slip of an electrical generator, in particular a synchronous generator, electrically connected to a power supply network, wherein a rotor of the generator is mechanically connected to an engine shaft of an internal combustion engine, in particular a gas engine, wherein the internal combustion engine is operated in a steady operating mode with a substantially constant mechanical rotational frequency and a pole slip identification device of corresponding configuration.

It is known that in the case of synchronous generators connected to a power supply network (for example a public power supply network or local power supply network in an island mode of operation) the rotor displacement angle or load angle expresses the deviation of the magnetic poles on the rotor of the generator from the magnetic poles on the stator of the generator. In that case the magnetic poles on the rotor are usually produced by a dc-fed exciter winding on the rotor and the magnetic poles on the stator of the generator are produced by electrical voltage, applied to corresponding windings on the stator, of the power supply network which is typically of a three-phase configuration. In the vector model therefore the rotor displacement angle describes the angle between the stator voltage and the rotor voltage or the pole wheel voltage, wherein the rotor voltage in the generator mode of operation of the synchronous generator leads the stator voltage. With a rising loading by the power supply network, that is to say in a case of increased power provision by the generator, that rotor displacement angle increases. If the rotor displacement angle becomes too great that leads to instability of the generator, in which the mechanical power introduced by the internal combustion engine by way of the engine shaft connected to the rotor can no longer be converted into electrical power as is desired and the internal combustion engine begins to speed up. That tipping into the unstable operating mode is known to be referred to as pole slip.

As pole slip and the acceleration linked thereto of the internal combustion engine can cause damage to the internal combustion engine and to the generator it is desirable to avoid or to detect pole slip in order to be able to react appropriately when pole slip is detected and to counteract acceleration of the internal combustion engine.

Therefore the object of the invention is to provide a simple method of identifying pole slip.

According to the invention that object is attained by a method having the features of claim 1 and by a pole slip identification device having the features of claim 9. Advantageous configurations of the invention are recited in the appendant claims.

According to the invention it is therefore provided that the mechanical rotational frequency of the engine shaft and an electrical rotational frequency of the power supply network are detected or ascertained, wherein upon a deviation in the mechanical rotational frequency from the electrical rotational frequency of greater than a predeterminable threshold value a signal is output, wherein the signal is considered as a detected pole slip.

When pole slip occurs the internal combustion engine begins to speed up, starting from its substantially constant rotary speed during the stable steady operating mode. That speeding-up can be recognized as a deviation in the mechanical rotational frequency of the engine shaft from the electrical rotational frequency of the stator voltage and can be detected as pole slip.

The advantage of the proposed method lies in particular in its simplicity. The sensor system required for detecting or ascertaining the mechanical and electrical rotational frequency is usually fitted in commercially available internal combustion engines and generators as usually the engine speed and the network frequency are monitored in the context of engine or generator monitoring systems. The proposed method therefore does not require any sensors which are additionally needed.

To avoid false alarms it can preferably be provided that the signal is output if the deviation of greater than the predeterminable threshold value occurs during a predeterminable period of time. In that way it is possible in particular to avoid a pole slip alarm being triggered during a process for synchronization of the generator with the power supply network.

In a particularly preferred embodiment it can be provided that in the event of detected pole slip the electrical connection between the electrical generator and the power supply network is separated. It can also be provided however that the output signal is used to provide that, when pole slip occurs that is signaled to a pole slip counter, whereupon the pole slip counter is incremented, wherein preferably a maintenance signal is output when the pole slip counter exceeds a predeterminable maintenance threshold value. In that respect it can be provided that the predeterminable maintenance threshold value is in a range of between 2 and 10, preferably between 3 and 5. Robust generators can certainly remain connected to the power supply network when pole slip occurs. It can therefore also be provided that the maintenance signal is utilized to separate the electrical connection between generator and power supply network only after an adjustable frequency of pole slips occurs. In general the occurrence of a respective pole slip can also be logged.

In a preferred embodiment of the invention it can be provided that a rotary engine speed or engine frequency of the engine shaft or a rotary rotor speed or rotor frequency of the rotor is detected or ascertained as the mechanical rotational frequency and a network frequency of the power supply network is detected or ascertained as the electrical rotational frequency, wherein the mechanical rotational frequency and the electrical rotational frequency are converted to the same unit by calculation. In that respect it can preferably be provided that the rotary engine speed of the engine shaft is detected as the mechanical rotational frequency and the network frequency of the power supply network is detected, wherein the network frequency is multiplied by a predeterminable multiplier as the electrical rotational frequency, wherein preferably the multiplier corresponds to the value of a division of the rotary engine speed in the steady operating mode of the internal combustion engine divided by the network frequency. Thus for example the detected rotary engine speed can be 3000 revolutions per minute and the detected network frequency can be 50 Hz. To be able to convert the two detected values to the same unit for example the detected network frequency can be multiplied by a multiplier whose value corresponds to a division of the detected engine speed divided by the network frequency, in this example therefore 3000 revolutions per minute divided by 50 Hz. Accordingly both the mechanical rotational frequency (3000 revolutions per minute) and also the electrical rotational frequency (3000 revolutions per minute) use the same unit.

In a preferred embodiment it can be provided that the predeterminable threshold value is greater than 10, preferably greater than 50, particularly preferably greater than 100, revolutions per minute.

Further details and advantages of the present invention will be described with reference to the specific description hereinafter. In the drawing:

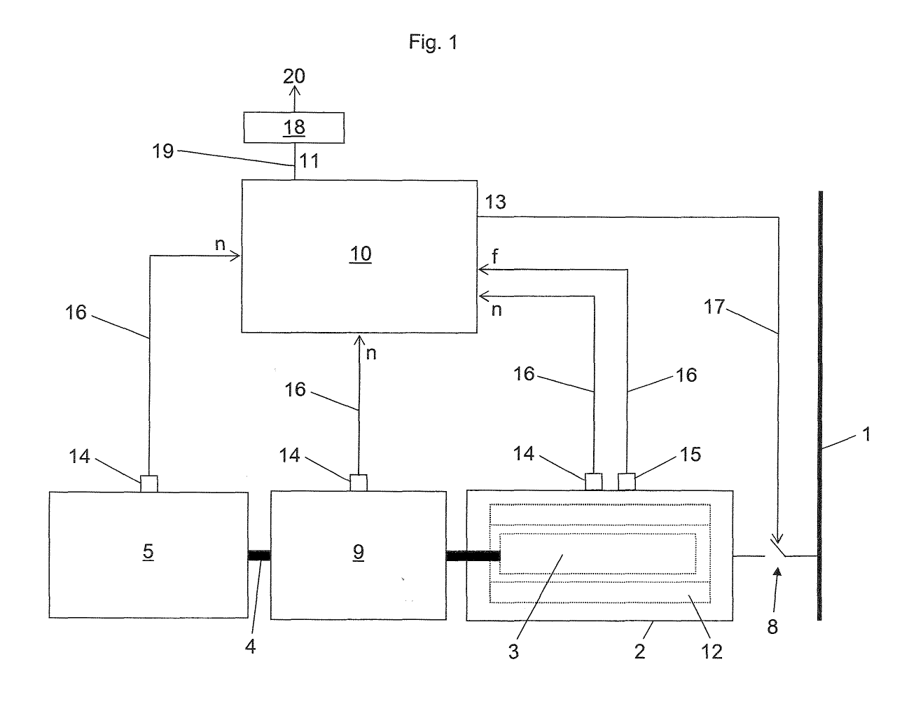

FIG. 1 shows a schematic block circuit diagram of a generator which is electrically connected to a power supply network and which is driven by an internal combustion engine,

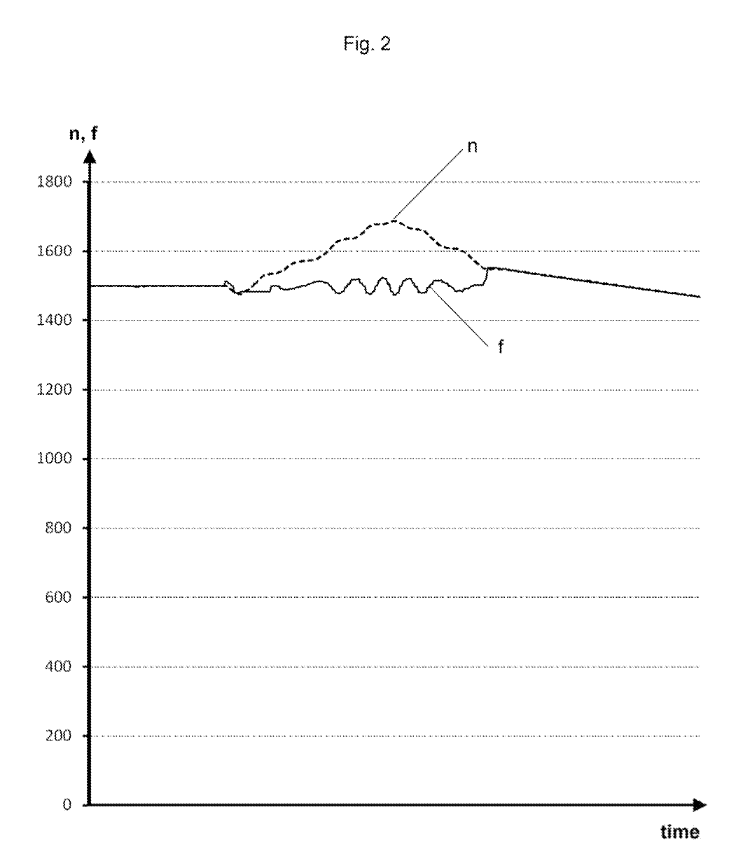

FIG. 2 shows the variation in respect of time of a deviation by way of example of mechanical rotational frequency relative to electrical rotational frequency, and

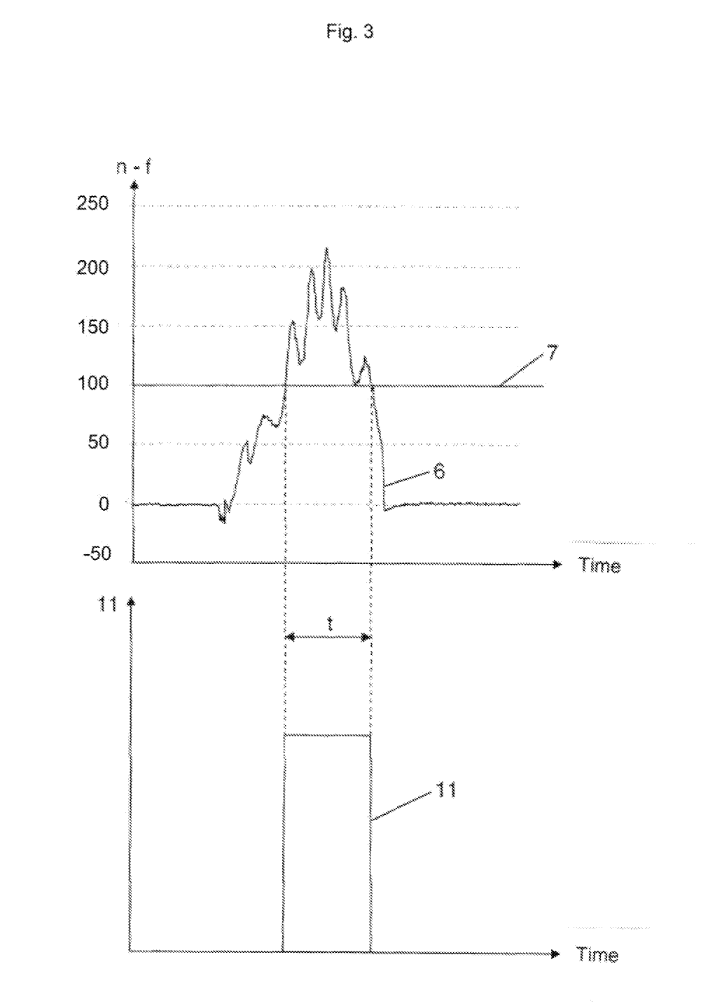

FIG. 3 shows a detail view of the deviation of FIG. 2 as well as pole slip identification.

FIG. 1 diagrammatically shows an electrical synchronous generator 2 connected by way of an electrical connecting device 8 in the form of a network switch to an electrical power supply network 1. The rotor 3 of the synchronous generator 2 is connected substantially non-rotatably to an engine shaft 4 of an internal combustion engine 5 by way of a coupling 9. The internal combustion engine 5 can be for example a stationary gas engine which is in the form of a spark-ignition four-stroke reciprocating piston engine. The power supply network 1 can have three phases, in the form of a three-phase network, wherein the three phases of the power supply network 1 can be connected to windings on the stator 12 of the generator 2 in known manner. The power supply network 1 may be a public power supply network which predetermines the network frequency or for example a local power supply network involving isolated island operation, in which the network frequency is predetermined by the generator.

For the proposed method a mechanical rotational frequency n and an electrical rotational frequency f of the power supply network 1 are now detected with sensors 14, 15 known in the state of the art and signaled to an evaluation unit 10 by way of signal lines 16. The sensor 14 for detecting the mechanical rotational frequency n can be for example a rotary speed sensor which is arranged at the internal combustion engine 5, the coupling 9 or the rotor 10 and which senses the tooth flanks of a toothed wheel and which ascertains the mechanical rotational frequency n from the detected time difference between sensing of the tooth flanks. The sensor 15 for detecting the electrical rotational frequency f of the power supply network 1 can be a network frequency sensor which for example detects the zero-crossings of the network voltage and ascertains the electrical rotational frequency f of the power supply network 1 from the detected time difference between the zero-crossings.

The mechanical rotational frequency n can therefore be for example the speed of rotation of the internal combustion engine 5 and the electrical rotational frequency f can be for example the network frequency of the power supply network 1. In that case detection of the mechanical rotational frequency n can be effected by means of the rotary speed sensor 14 directly at the engine shaft 4 of the internal combustion engine 5, in the coupling or for example also at the rotating rotor of the generator 2. Detection of the electrical rotational frequency f can be effected by means of the network frequency sensor 15 at the stator 12 of the generator 2.

To be able to ascertain a deviation between mechanical rotational frequency n and electrical rotational frequency f it is optionally possible to provide for conversion of mechanical rotational frequency n and/or electrical rotational frequency f so that both the mechanical rotational frequency n and also the electrical rotational frequency f involve the same unit.

The evaluation unit 10 continuously ascertains the deviation 6 in the mechanical rotational frequency n from the electrical rotational frequency f, wherein in the event of a deviation 6 of greater than a predeterminable threshold value 7 a signal 11 is output, the signal 11 being considered as detected pole slip (see FIG. 2). In the illustrated example the signal 11 is passed by way of a counting line 19 to a pole slip counter 18 which counts the occurrence of detected pole slip and outputs a maintenance signal 20 when a predeterminable maintenance threshold value is exceeded.

It can also be provided that the signal 11 is passed to a monitoring device of the generator 2 or the internal combustion engine 5.

It can preferably also be provided that the electrical connecting device 8 between the electrical generator 2 and the power supply network 1 is separated when pole slip is detected. For those purposes for example the evaluation unit 10 can send a corresponding switching signal 13 to the electrical connecting device 8 by way of a switching line 17, wherein separation of the electrical connection is triggered by the switching signal 13 by opening of the connecting device 8.

FIG. 2 shows by way of example variations in respect of time of mechanical rotational frequency n and electrical rotational frequency f of the power supply network 1 of an arrangement as shown in FIG. 1. In this case the target rotary speed is 1500 revolutions per minute. It will be seen from the drawing that the mechanical rotational frequency n differs at times from the electrical rotational frequency f.

FIG. 3 shows the variation in respect of time of the deviation 6, detected by the evaluation unit 10, in the mechanical rotational frequency n from the electrical rotational frequency f as shown in FIG. 2. This example involves a threshold value 7 of 100 revolutions per minute. In other words, in the event of a deviation 6 of more than 100 revolutions per minute a signal 11 is output, which is considered as detected pole slip. As can be seen from the drawing that threshold value 7 is exceeded during the period of time t whereby a corresponding signal 11 is output during the period of time t.

1. A method of identifying pole slip of an electrical generator, in particular a synchronous generator, electrically connected to a power supply network, wherein a rotor of the generator is mechanically connected to an engine shaft of an internal combustion engine, in particular a gas engine, wherein the internal combustion engine is operated in a steady operating mode with a substantially constant mechanical rotational frequency, wherein the mechanical rotational frequency of the engine shaft and an electrical rotational frequency of the power supply network are detected or ascertained, wherein upon a deviation in the mechanical rotational frequency from the electrical rotational frequency of greater than a predeterminable threshold value a signal is output, wherein the signal is considered as a detected pole slip.

2. A method as set forth in claim 1, wherein the signal is output if the deviation of greater than the predeterminable threshold value occurs during a predeterminable period of time.

3. A method as set forth in claim 1, wherein in the event of detected pole slip the electrical connection between the electrical generator and the power supply network is separated.

4. A method as set forth in claim 1, wherein a rotary engine speed or engine frequency of the engine shaft or a rotary rotor speed or rotor frequency of the rotor is detected or ascertained as the mechanical rotational frequency and a network frequency of the power supply network is detected or ascertained as the electrical rotational frequency, wherein the mechanical rotational frequency and the electrical rotational frequency are converted to the same unit by calculation.

5. A method as set forth in claim 4, wherein the rotary engine speed of the engine shaft is detected as the mechanical rotational frequency and the network frequency of the power supply network is detected, wherein the network frequency is multiplied by a predeterminable multiplier as the electrical rotational frequency, wherein preferably the multiplier corresponds to the value of a division of the rotary engine speed in the steady operating mode of the internal combustion engine divided by the network frequency.

6. A method as set forth in claim 1, wherein the predeterminable threshold value is greater than 10, preferably greater than 50, particularly preferably greater than 100, revolutions per minute.

7. A method as set forth in claim 1, wherein the signal is signaled to a pole slip counter, wherein the pole slip counter is incremented, wherein preferably a maintenance signal is output when the pole slip counter exceeds a predeterminable maintenance threshold value.

8. A method as set forth in claim 7, wherein the predeterminable maintenance threshold value is in a range of between 2 and 10, preferably between 3 and 5.

9. A pole slip identification device, in particular for carrying out a method as set forth in claim 1, for the identification of pole slip of an electrical generator, in particular a synchronous generator, electrically connected to a power supply network, wherein a rotor of the generator is mechanically connected to an engine shaft of an internal combustion engine, in particular a gas engine, wherein there are provided a rotary speed sensor for detecting a mechanical rotational frequency of the engine shaft and a network frequency sensor for detecting an electrical rotational frequency of the power supply network, characterised in that wherein there is provided an evaluation unit, wherein the detected mechanical rotational frequency and the detected electrical rotational frequency can be signaled to the evaluation unit by way of signal lines, wherein a deviation in the mechanical rotational frequency from the electrical rotational frequency can be ascertained by the evaluation unit, wherein upon a deviation of greater than a predeterminable threshold value a signal considered as detected pole slip can be output by the evaluation unit.

10. A pole slip identification device as set forth in claim 9, wherein the electrical generator is electrically connected to the power supply network by way of a connecting device preferably a network switch, wherein when pole slip is detected a switching signal can be signaled to the connecting device by the evaluation unit by way of a switching line, wherein opening of the connecting device can be triggered by the switching signal.

11. A pole slip identification device as set forth in claim 9, wherein there is provided a—preferably incrementable—pole slip counter, wherein the signal can be signaled to the pole slip counter by way of a counting line, wherein preferably a maintenance signal can be output when the pole slip counter exceeds a predeterminable maintenance threshold value.
